(19) United States
(12) Patent Application Publication
(10) Pub. No.: US 2025/0176143 A1
(43) Pub. Date: May 29, 2025

(54) SEPARABLE HEATSINK DESIGN

(71) Applicant: DELL PRODUCTS L.P., Round Rock, TX (US)

(72) Inventors: Sih-Hao Liou, Luzhou District (TW); Wen-Hung Lu, Taipei (TW); Ming-Hui Pan, New Taipei City (TW); Lawrence Ying-Hsi Lin, Zhongzheng District (TW)

(21) Appl. No.: 18/521,699

(22) Filed: Nov. 28, 2023

(51) Int. Cl. H05K 7/20; H05K 7/14

(52) U.S. Cl. CPC H05K 7/2039; H05K 7/1402

(57) ABSTRACT

A heatsink includes a main body, a hinge, an arm portion, and a latch. The arm portion is in physical communication with the main body and with the hinge. The arm portion includes a movable portion that transitions between a closed position and an open position. The latch is in physical communication with the movable portion of the arm portion. The latch transitions between a locked position and an unlocked position. The latch securely holds the movable portion in the closed position.

### FIELD OF THE DISCLOSURE

The present disclosure generally relates to information handling systems, and more particularly relates to a separable heatsink design.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A heatsink includes a main body, a hinge, an arm portion, and a latch. The arm portion is in physical communication with the main body and with the hinge. The arm portion includes a movable portion that may transition between a closed position and an open position. The latch is in physical communication with the movable portion of the arm portion. The latch may transition between a locked position and an unlocked position. The latch may securely hold the movable portion in the closed position.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a heatsink according to at least one embodiment of the present disclosure;

FIG. 2 is an internal view of a heatsink according to at least one embodiment of the present disclosure;

FIGS. 3 and 4 are cross-sectional views of a heatsink according to at least one embodiment of the present disclosure;

FIG. 5 is a diagram of a heatsink including multiple latches according to at least one embodiment of the present disclosure;

FIGS. 6 and 7 are side views of a heatsink according to at least one embodiment of the present disclosure;

FIGS. 8 and 9 are side views of a portion of a heatsink including a first embodiment of a latch according to at least one embodiment of the present disclosure;

FIGS. 10 and 11 are side views of a portion of a heatsink including a second embodiment of the latch according to at least one embodiment of the present disclosure;

FIGS. 12-14 are side views of a portion of a heatsink including the second embodiment of the latch in different stages according to at least one embodiment of the present disclosure; and

FIG. 15 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

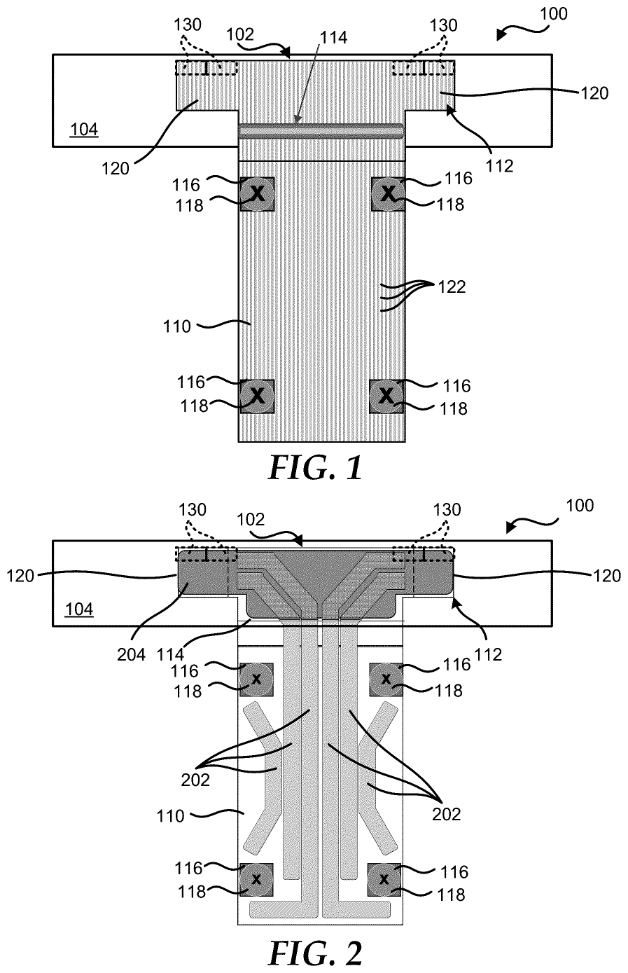

FIGS. 1 and 2 illustrate a portion of an information handling system 100 according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Information handling system 100 includes a heatsink 102 and a printed circuit board (PCB) 104. Heatsink 102 includes a main body 110, an arm portion 112, a hinge 114, multiple mounting locations 116, and multiple mounted screws 118. Arm portion 112 includes extension sections 120 and 122 that extend in opposite directions beyond edges of main body 110. PCB 104 includes multiple connectors 130 that may be located below extension portions 120 and 122 of arm portion 112. Hinge 114 is in physical communication with both main body 110 and arm portion 112. While arm portion 112 is illustrated with sections 120 and 122, the arm portion may only include a single extension section without varying from the scope of this disclosure. Heatsink 102 may include additional components without varying from the scope of this disclosure.

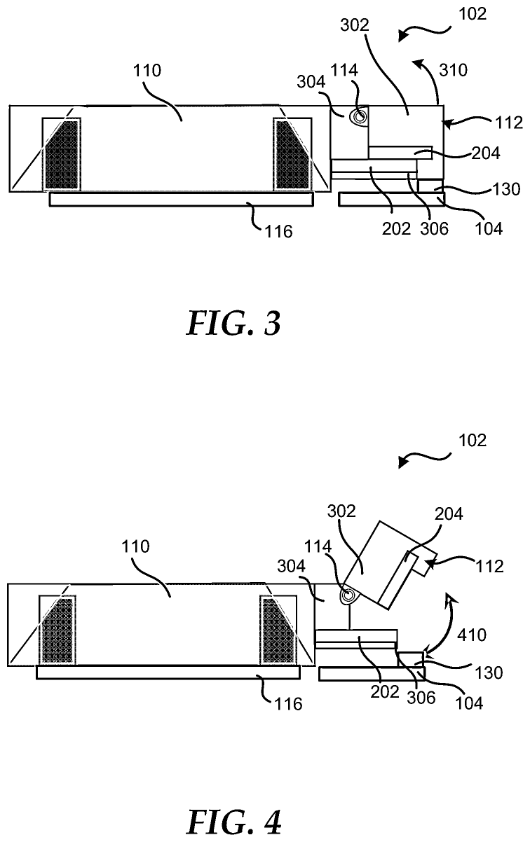

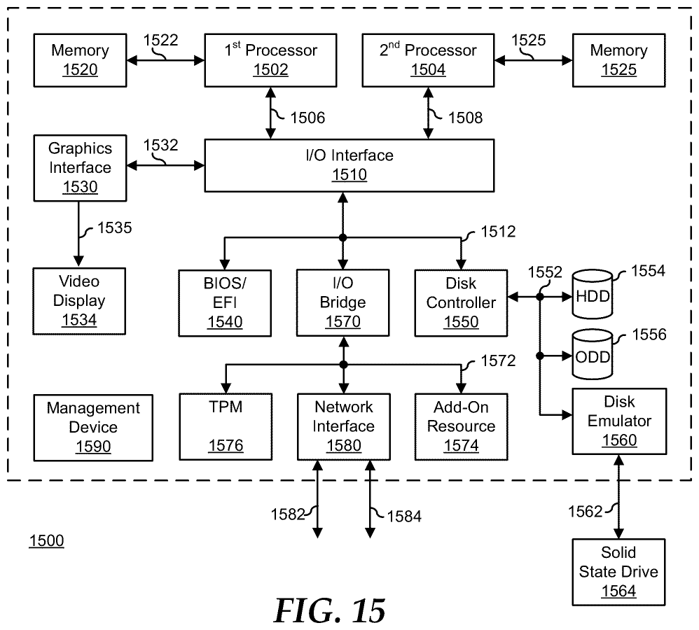

In an example, heatsink 102 may be secured in physical communication with a component, such as processor 330 of FIGS. 3 and 4, or processor 1502 or 1504 of FIG. 15, on PCB 104 to provide thermal cooling of the component. Screws 118 may be inserted through mounting locations 116 and connect within mounting holes of PCB 104. Based on the shape of heatsink 102, the heatsink may provide more surface area for an airflow to travel across fins 122 of the heatsink. For example, fins 122 within main body 110 and arm portion 112 may provide heat transfer from a component of an information handling system, such as processor 1502 or 1504 of information handling system 1500 in FIG. 15, to an airflow.

Referring now to FIG. 2, a cross section of heatsink 102 illustrates multiple heat pipes 202 and a thermal conductor material 204. Heat pipes 202 may be located within heatsink 102 to move heat from a component to the fins 122 of the heatsink. In an example, thermal conductor material 204 may be in physical communication with heat pipes 202. Based on the physical communication, thermal conductor material 204 may conduct heat from heat pipes 202 to fins 122 of heat sink 102. In certain examples, arm portion 112 may rotate around hinge 114 and transition from a closed position to an open position. When arm portion 112 is in the closed position, extension portions 120 and 122 may cover connectors 130 on PCB 104. When arm portion 112 is in the open position, space may be provided to enable an individual to access connectors 130 on PCB 104. Based on the access to connectors 130, the individual may plug/unplug cabled from the connectors.

FIGS. 3 and 4 illustrate side cross section views of heatsink 102 according to at least one embodiment of the present disclosure. FIG. 3 shows arm portion 112 in a closed position and FIG. 4 shows the arm portion in an open position. Arm portion 112 includes a movable portion 302, a static upper portion 304 and a static lower portion 306. Static upper and lower portions 304 and 306 are securely and permanently connected to main body 110. Movable portion 302 is rotatably coupled to static upper portion 304 via hinge 114. Thermal conductor material 204 is located within movable portion 302 and heat pipes 202 are located within static lower portion 306. Main body 110 is in physical communication with processor 130 to transfer heat from the processor.

Referring now to FIG. 3, when arm portion 112 is in the closed position, thermal conductor material 204 is in physical communication with heat pipes 202. In an example, the physical communication between thermal conductor material 204 and heat pipes 202 may enable heat from a component, such as a component on PCB 104 of FIG. 1, to be transferred from the heat pipes to the thermal conductor material. When arm portion 112 is in the closed position, connectors 130 on PCB 104 are not accessible to an individual. In an example, a force may be applied to movable portion 302 in the direction of arrow 310 to transition arm portion 112 from the closed position to the opened position.

Referring now to FIG. 4, when arm portion 112 is in the open position, thermal conductor material 204 is not in physical communication with heat pipes 202. In an example, movable portion 302 may be located any suitable distance away from connectors 130 and heat pipes 202 when arm portion 112 is in the open position. This distance may enable an individual access to connectors 130 on PCB 104. In certain examples, the individual may plug/unplug cables into/out of connectors 130 when arm portion 112 is in the open position. In an example, a force may be applied to movable portion 302 in the direction of arrow 410 to transition arm portion 112 from the open position to the closed position.

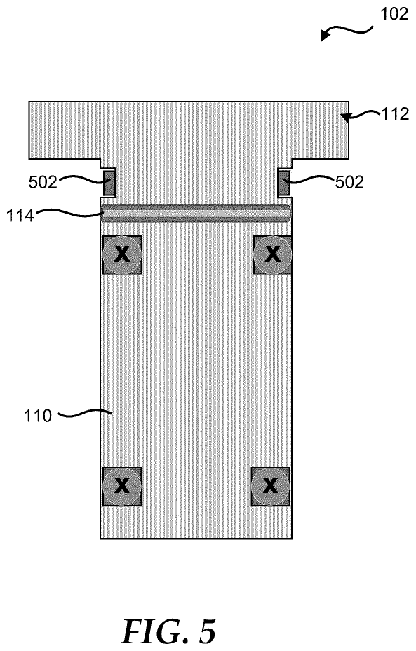

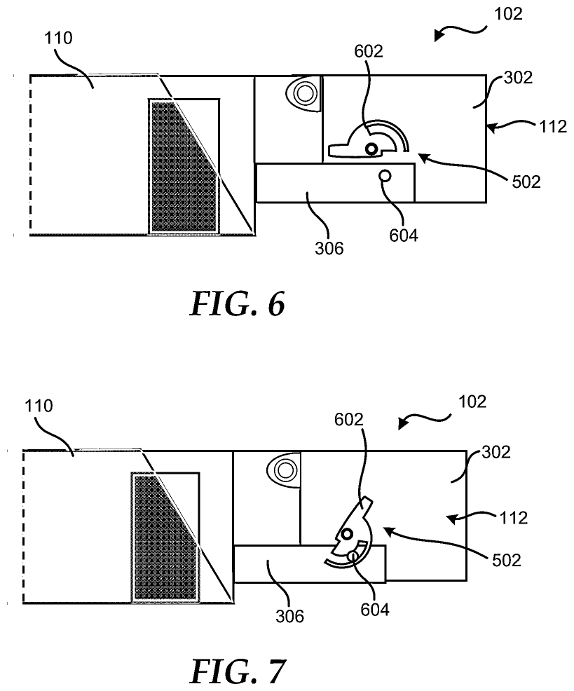

FIG. 5 illustrates heatsink 102 including multiple latches 502, main body 110, arm portion 112, and hinge 114 according to at least one embodiment of the present disclosure. Latches 502 may be located on side surfaces of arm portion 112. In an example, latches 502 may be located within recesses 504 of arm portion 112. In this example, latches 502 may not extend beyond respective recesses 504, such that the latches are fully with arm portion 112 and do not interfere with other components of an information handling system. While two latches 502 are illustrated in FIG. 5, any suitable number of latches may be used to secure arm portion 112 in the closed position. In an example, latches 502 rotate between unlocked and locked positions as illustrated in respective FIGS. 6 and 7 below.

FIGS. 6 and 7 illustrate side views of heatsink 102 according to at least one embodiment of the present disclosure. Latch 502 includes a rotating component 602 and a pin 604. Rotating component 602 is mounted on movable portion 302 of arm portion 112. Pin 604 is permanently secured on static lower portion 306. In an example, rotating component 602 may be mounted in such a manner to enable the rotating component to rotate between an open position and a locked position of latch 502. When rotating component 602 is disengaged from pin 604, as shown in FIG. 6, arm portion 112 is in the unlocked position. When rotating component 602 is engaged with pin 604, as shown in FIG. 7, arm portion 112 is in the locked position.

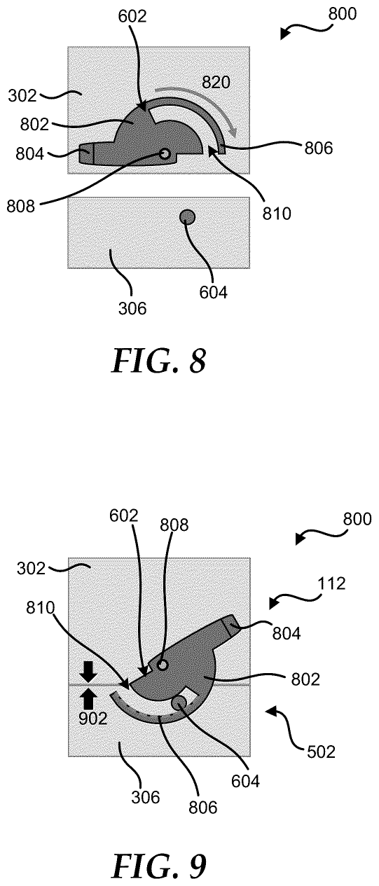

FIGS. 8 and 9 are side views of a portion 800 of heatsink 102 of FIGS. 1-7, according to at least one embodiment of the present disclosure. Rotating component 602 includes a main portion 802, a tab 804, a hook 806, a pin 808, and a channel 810. Channel 810 is located between main portion 802 and hook 806. In an example, a width of channel 810 may be substantially equal to the diameter of pin 604 on static lower portion 306. In certain examples, an individual may exert a force on tab 804, and this force may cause main portion 802, hook 806, and channel 810 to rotate in the direction of arrow 820 around pin 808. As rotating component 602 continues to rotate in the direction of arrow 820, pin 604 may come in physical communication with the rotating component. For example, pin 604 slide within channel 810 and be in physical communication with main portion 802 and hook 806.

Referring now to FIG. 9, as pin 604 continues to slide within channel 810, latch 502 may pull movable portion 302 toward static lower portion 306. In an example, the movement of movable portion 302 toward static lower portion 306 may cause the gap between these portions to close as indicated by arrows 902 in FIG. 9. When pin 604 is located at the end of channel 810 that is distal from the opening of the channel, latch 502 may be locked and arm portion 112 may be securely held in the closed position.

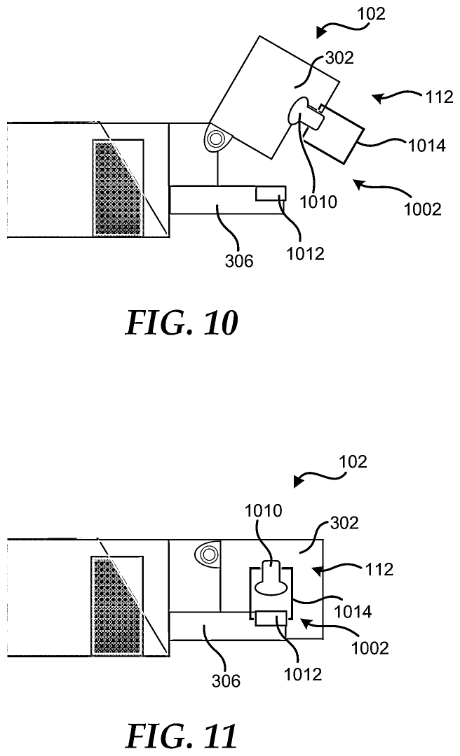

FIGS. 10 and 11 illustrate side views of heatsink 102 with another embodiment of a latch 1002 for arm portion 112 according to at least one embodiment of the present disclosure. Latch 1002 includes a swing portion 1010, a keeper portion 1012, and a hook 1014. Swing portion 1010 is mounted on movable portion 302 of arm portion 112. Keeper portion 1012 is permanently secured on static lower portion 306. In an example, swing portion 1010 may be mounted in such a manner to enable latch 1002 to transition between an unlocked position and a locked position. When hook 1014 is disengaged from keeper portion 1012, as shown in FIG. 10, arm portion 112 is in the unlocked/open position. When hook 1014 is engaged with keeper portion 1012, as shown in FIG. 11, arm portion 112 is in the locked/closed position.

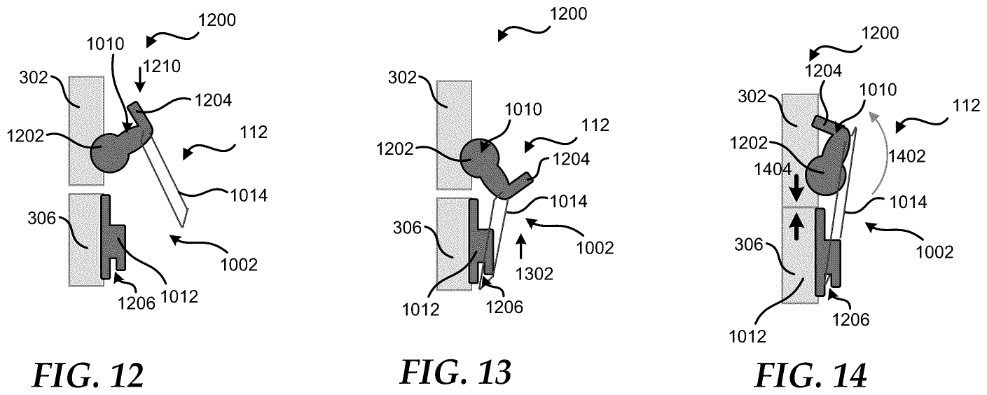

FIGS. 12-14 are side views of a portion 1200 of heatsink 102 of FIGS. 1-7, according to at least one embodiment of the present disclosure. FIG. 12 illustrates latch 1002 in an unlocked position, FIG. 13 illustrates latch 1002 in an intermediate position, and FIG. 14 illustrates latch 1002 in a locked position. Swing portion 1010 includes a main portion 1202 and a tab 1204. Keeper portion 1012 includes a slot 1206 that may receive hook 1014 as will be described herein.

Referring now to FIG. 12, when latch 1002 is in the unlocked position, tab 1204 of swing position 1010 may be located away from movable portion 302. In the unlocked position, movable portion 302 may not be held in physical communication with static portion 306, such that arm portion 112 may be transitioned to the open position as described with respect to FIGS. 3 and 4 above. In an example, an individual may exert a force on tab 1204 in the direction of arrow 1210 to transition latch 1002 from the unlocked position to an intermediate position as illustrated in FIG. 13.

Referring now to FIG. 13, when latch 1002 is in the intermediate position, swing portion 1010 may be positioned so that hook 1014 may extend beyond keeper 1012. When hook 1014 is beyond keeper 1012, the individual may align a portion of the hook with slot 1206 of the keeper. In an example, the individual may exert a force on tab 1204 in the direction of arrow 1302 to transition latch 1002 from the intermediate position to an unlocked position as shown in FIG. 14.

Referring now to FIG. 14, based on the force from the individual, swing portion 1010 may rotate in the direction of arrow 1402. This rotation of swing portion 1010, may pull hook 1014 within slot 1206 of keeper 1012. As swing portion 1010 fully rotates in the direction of arrow 1402, hook 1014 may exert a force on keeper 1012. In an example, the force exerted by hook 1014 on keeper 1012 may pull movable portion 302 toward static lower portion 306. In an example, the movement of movable portion 302 toward static lower portion 306 may cause the gap between these portions to close as indicated by arrows 1404 in FIG. 14. When latch 1002 is in the locked position, arm portion 112 may be securely held in the closed position.

FIG. 15 shows a generalized embodiment of an information handling system 1500 according to an embodiment of the present disclosure. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 1500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 1500 can include processing resources for executing machine-executable code, such as a central processing unit (CPU), a programmable logic array (PLA), an embedded device such as a System-on-a-Chip (SoC), or other control logic hardware. Information handling system 1500 can also include one or more computer-readable medium for storing machine-executable code, such as software or data. Additional components of information handling system 1500 can include one or more storage devices that can store machine-executable code, one or more communications ports for communicating with external devices, and various input and output (I/O) devices, such as a keyboard, a mouse, and a video display. Information handling system 1500 can also include one or more buses operable to transmit information between the various hardware components.

Information handling system 1500 can include devices or modules that embody one or more of the devices or modules described below and operates to perform one or more of the methods described below. Information handling system 1500 includes a processors 1502 and 1504, an input/output (I/O) interface 1510, memories 1520 and 1525, a graphics interface 1530, a basic input and output system/universal extensible firmware interface (BIOS/UEFI) module 1540, a disk controller 1550, a hard disk drive (HDD) 1554, an optical disk drive (ODD) 1556, a disk emulator 1560 connected to an external solid state drive (SSD) 1562, an I/O bridge 1570, one or more add-on resources 1574, a trusted platform module (TPM) 1576, a network interface 1580, a management device 1590, and a power supply 1595. Processors 1502 and 1504, I/O interface 1510, memory 1520, graphics interface 1530, BIOS/UEFI module 1540, disk controller 1550, HDD 1554, ODD 1556, disk emulator 1560, SSD 1562, I/O bridge 1570, add-on resources 1574, TPM 1576, and network interface 1580 operate together to provide a host environment of information handling system 1500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 1500.

In the host environment, processor 1502 is connected to I/O interface 1510 via processor interface 1506, and processor 1504 is connected to the I/O interface via processor interface 1508. Memory 1520 is connected to processor 1502 via a memory interface 1522. Memory 1525 is connected to processor 1504 via a memory interface 1527. Graphics interface 1530 is connected to I/O interface 1510 via a graphics interface 1532 and provides a video display output 1536 to a video display 1534. In a particular embodiment, information handling system 1500 includes separate memories that are dedicated to each of processors 1502 and 1504 via separate memory interfaces. An example of memories 1520 and 1530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 1540, disk controller 1550, and I/O bridge 1570 are connected to I/O interface 1510 via an I/O channel 1512. An example of I/O channel 1512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 1510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 1540 includes BIOS/UEFI code operable to detect resources within information handling system 1500, to provide drivers for the resources, initialize the resources, and access the resources. BIOS/UEFI module 1540 includes code that operates to detect resources within information handling system 1500, to provide drivers for the resources, to initialize the resources, and to access the resources.

Disk controller 1550 includes a disk interface 1552 that connects the disk controller to HDD 1554, to ODD 1556, and to disk emulator 1560. An example of disk interface 1552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 1560 permits SSD 1564 to be connected to information handling system 1500 via an external interface 1562. An example of external interface 1562 includes a USB interface, an IEEE 4394 (Firewire) interface, a proprietary interface, or a combination thereof. Alternatively, solid-state drive 1564 can be disposed within information handling system 1500.

I/O bridge 1570 includes a peripheral interface 1572 that connects the I/O bridge to add-on resource 1574, to TPM 1576, and to network interface 1580. Peripheral interface 1572 can be the same type of interface as I/O channel 1512 or can be a different type of interface. As such, I/O bridge 1570 extends the capacity of I/O channel 1512 when peripheral interface 1572 and the I/O channel are of the same type, and the I/O bridge translates information from a format suitable to the I/O channel to a format suitable to the peripheral channel 1572 when they are of a different type. Add-on resource 1574 can include a data storage system, an additional graphics interface, a network interface card (NIC), a sound/video processing card, another add-on resource, or a combination thereof. Add-on resource 1574 can be on a main circuit board, on separate circuit board or add-in card disposed within information handling system 1500, a device that is external to the information handling system, or a combination thereof.

Network interface 1580 represents a NIC disposed within information handling system 1500, on a main circuit board of the information handling system, integrated onto another component such as I/O interface 1510, in another suitable location, or a combination thereof. Network interface device 1580 includes network channels 1582 and 1584 that provide interfaces to devices that are external to information handling system 1500. In a particular embodiment, network channels 1582 and 1584 are of a different type than peripheral channel 1572 and network interface 1580 translates information from a format suitable to the peripheral channel to a format suitable to external devices. An example of network channels 1582 and 1584 includes InfiniBand channels, Fibre Channel channels, Gigabit Ethernet channels, proprietary channel architectures, or a combination thereof. Network channels 1582 and 1584 can be connected to external network resources (not illustrated). The network resource can include another information handling system, a data storage system, another network, a grid management system, another suitable resource, or a combination thereof.

Management device 1590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 1500. In particular, management device 1590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 1500, such as system cooling fans and power supplies. Management device 1590 can include a network connection to an external management system, and the management device can communicate with the management system to report status information for information handling system 1500, to receive BIOS/UEFI or system firmware updates, or to perform other task for managing and controlling the operation of information handling system 1500.

Management device 1590 can operate off of a separate power plane from the components of the host environment so that the management device receives power to manage information handling system 1500 when the information handling system is otherwise shut down. An example of management device 1590 include a commercially available BMC product or other device that operates in accordance with an Intelligent Platform Management Initiative (IPMI) specification, a Web Services Management (WSMan) interface, a Redfish Application

Programming Interface (API), another Distributed Management Task Force (DMTF), or other management standard, and can include an Integrated Dell Remote Access Controller (iDRAC), an Embedded Controller (EC), or the like. Management device 1590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A heatsink comprising:
a main body;
a hinge;
an arm portion in physical communication with the main body and with the hinge, the arm portion including a movable portion configured to transition between a closed position and an open position; and
a latch in physical communication with the movable portion of the arm portion, the latch to transition between a locked position and an unlocked position, wherein the latch to securely hold the movable portion in the closed position.

2. The heatsink of claim 1, further comprising a static upper portion in physical communication with in the main body and with the hinge, wherein the static upper portion is coupled to the movable portion via the hinge.

3. The heatsink of claim 1, further comprising a static lower portion in physical communication with in the main body, wherein the static lower portion includes a plurality of heat pipes.

4. The heatsink of claim 3, wherein the movable portion includes a heat transfer material, wherein the heat transfer material is in physical communication with the heat pipes when the movable portion is in the closed position.

5. The heatsink of claim 3, wherein the heat pipes are located within both the main body and the static lower portion.

6. The heatsink of claim 3, wherein the movable portion is not in phsycial communciation with the static lower portion when the movable portion is in the open position.

7. The heatsink of claim 1, wherein the movable portion transitions from the closed position to the open position when the latch is in the unlocked position.

8. The heatsink of claim 1, wherein in response to a force being exerted on the movable portion, the movable portion rotates around the hinge.

9. An information handling system comprising:
a printed circuit board including a plurality of connectors; and
a heatsink in physical communication with the printed circuit board, the heatsink including;
an arm portion in physical communication with a main body and with a hinge, the arm portion including a movable portion configured to transition between a closed position and an open position; and
a latch in physical communication with the movable portion of the arm portion, the latch to transition between a locked position and an unlocked position, wherein the latch to securely hold the movable portion in the closed position.

10. The information handling system of claim 9, wherein the heatsink further includes a static upper portion in physical communication with in the main body and with the hinge, wherein the static upper portion is coupled to the movable portion via the hinge.

11. The information handling system of claim 9, wherein the heatsink further includes a static lower portion in physical communication with in the main body, wherein the static lower portion includes a plurality of heat pipes.

12. The information handling system of claim 11, wherein the movable portion includes a heat transfer material, wherein the heat transfer material is in physical communication with the heat pipes when the movable portion is in the closed position.

13. The information handling system of claim 11, wherein the heat pipes are located within both the main body and the static lower portion.

14. The information handling system of claim 11, wherein the movable portion is not in phsycial communciation with the static lower portion when the movable portion is in the open position, and the connectors are visible when the movable portion is in the open position.

15. The information handling system of claim 9, wherein the movable portion transitions from the closed position to the open position when the latch is in the unlocked position.

16. The information handling system of claim 9, wherein in response to a force being exerted on the movable portion, the movable portion rotates around the hinge.

17. An information handling system comprising:
a processor;
a printed circuit board including a plurality of connectors; and
a heatsink in physical communication with the printed circuit board, the heatsink including:
a main body in physical communication with the processor;
an arm portion in physical communication with the main body and with a hinge, the arm portion including a movable portion configured to transition between a closed position and an open position; and
a latch in physical communication with the movable portion of the arm portion, the latch to transition between a locked position and an unlocked position, wherein the latch to securely hold the movable portion in the closed position.

18. The information handling system of claim 17, wherein the heatsink further includes a static upper portion in physical communication with in the main body and with the hinge, wherein the static upper portion is coupled to the movable portion via the hinge.

19. The information handling system of claim 17, wherein the heatsink further includes a static lower portion in physical communication with in the main body, wherein the static lower portion includes a plurality of heat pipes.

20. The information handling system of claim 19, wherein the movable portion includes a heat transfer material, wherein the heat transfer material is in physical communication with the heat pipes when the movable portion is in the closed position.
